(19) United States
(12) Patent Application Publication
(10) Pub. No.: US 2007/0272044 A1
(43) Pub. Date: Nov. 29, 2007

(54) Remote controller assembly that is mounted easily and conveniently

(75) Inventor: Hsin-Ming Huang, Taichung City (TW)

Correspondence Address: KAMRATH & ASSOCIATES P.A., 4825 OLSON MEMORIAL HIGHWAY, SUITE 245, GOLDEN VALLEY, MN, 55422, US

(73) Assignee: GRAND MATE CO., LTD., Taichung City (TW)

(21) Appl. No.: 11/439,159

(22) Filed: May 23, 2006

(51) Int. Cl. H03J 1/18

(52) U.S. Cl. 74/10 A

(57) ABSTRACT

A remote controller assembly includes remote controller assembly, comprising a remote controller, and a fixture detachably mounted on the remote controller. Thus, the fixture is fully hidden in the back face of the remote controller, so that the fixture is not exposed from the remote controller, thereby enhancing the aesthetic quality of the remote controller. In addition, the sliding space of the fixture is slidable on the mounting seat of the remote controller, and the guide hooks of the fixture are guided by the guide rails of the mounting seat when the remote controller is axially movable toward the fixture, so that the remote controller is attached to the fixture easily and rapidly, thereby facilitating a user attaching the remote controller to the fixture.

### BACKGROUND OF THE INVENTION

1. Field of the Invention

The present invention relates to a remote controller assembly and, more particularly, to a remote controller assembly that is mounted easily and conveniently.

2. Description of the Related Art

A conventional remote controller contains an emitter that sends a wireless signal to an electric appliance, such as the television and the like, so as to turn on and turn off the electric appliance, so that the electric appliance is operated distantly by control of the remote controller, thereby facilitating a user operating the electric appliance at a distant position. However, the remote controller has a smaller volume, so that it is easily lost when not in use, thereby causing inconvenience to the user.

### BRIEF SUMMARY OF THE INVENTION

In accordance with the present invention, there is provided a remote controller assembly, comprising a remote controller, and a fixture detachably mounted on the remote controller and fully hidden in a back face of the remote controller.

The primary objective of the present invention is to provide a remote controller assembly that is mounted easily and conveniently.

Another objective of the present invention is to provide a remote controller assembly, wherein the fixture is fully hidden in the back face of the remote controller, so that the fixture is not exposed from the remote controller, thereby enhancing the aesthetic quality of the remote controller.

A further objective of the present invention is to provide a remote controller assembly, wherein the sliding space of the fixture is slidable on the mounting seat of the remote controller, and the guide hooks of the fixture are guided by the guide rails of the mounting seat when the remote controller is axially movable toward the fixture, so that the remote controller is attached to the fixture easily and rapidly, thereby facilitating a user attaching the remote controller to the fixture.

A further objective of the present invention is to provide a remote controller assembly, wherein the reinforcing ribs of the plug are closely rested on the outer side of the slot when the plug is inserted into the slot of the socket to prevent the remote controller from being swayed or vibrated.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a rear perspective view of a remote controller assembly in accordance with the preferred embodiment of the present invention.

FIG. 2 is an exploded perspective view of the remote controller assembly as shown in FIG. 1.

FIG. 3 is a side plan operational view of the remote controller assembly as shown in FIG. 2.

FIG. 4 is a side plan view of the remote controller assembly as shown in FIG. 1.

FIG. 5 is a front perspective view of the remote controller assembly as shown in FIG. 1.

FIG. 6 is a front perspective view of a remote controller assembly in accordance with another preferred embodiment of the present invention.

FIG. 7 is a front perspective view of a remote controller assembly in accordance with another preferred embodiment of the present invention.

FIG. 8 is another perspective view of the remote controller assembly as shown in FIG. 7.

### DETAILED DESCRIPTION OF THE INVENTION

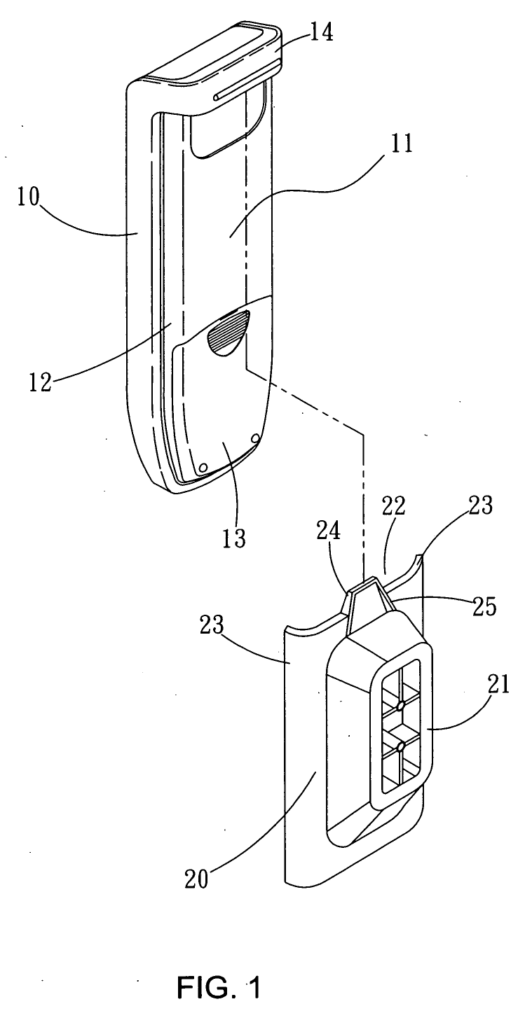

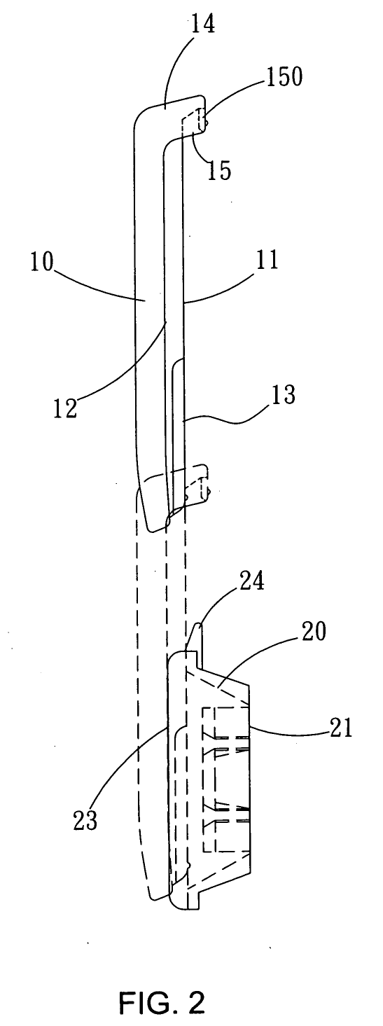

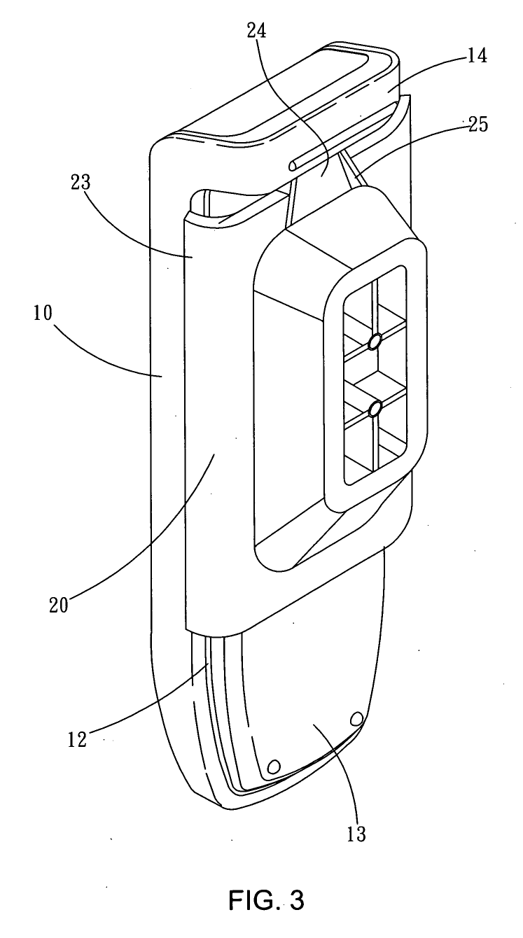

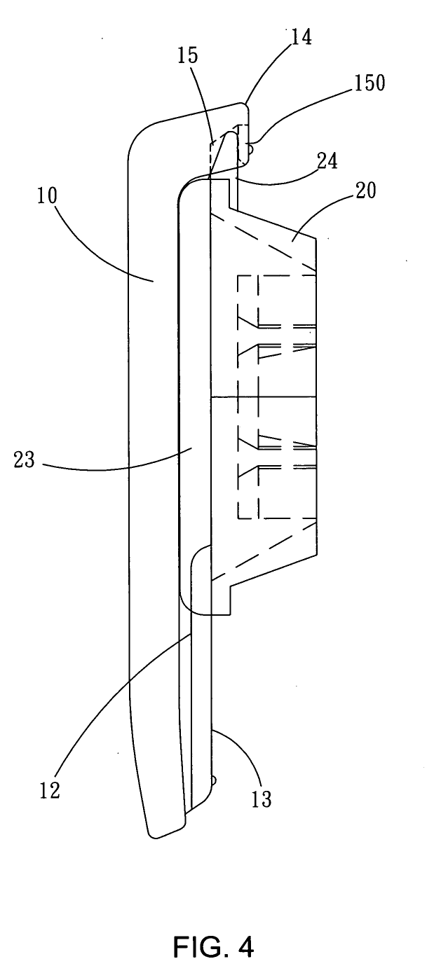

Referring to the drawings and initially to FIGS. 1-4, a remote controller assembly in accordance with the preferred embodiment of the present invention comprises a remote controller 10, and a fixture 20 detachably mounted on the remote controller 10 and fully hidden in a back face of the remote controller 10.

The back face of the remote controller 10 is formed with a protruding mounting seat 11 to support the fixture 20. The mounting seat 11 of the remote controller 10 has two opposite sides formed with two parallel guide rails 12 respectively. The two guide rails 12 of the mounting seat 11 have a distance smaller than a width of the remote controller 10. Each of the two guide rails 12 of the mounting seat 11 is gradually reduced toward a back face thereof. Each of the two guide rails 12 of the mounting seat 11 has a lower portion gradually reduced downward. The remote controller 10 has an upper end formed with an outwardly extending socket 14 located above the mounting seat 11 and a lower end provided with a battery box 13 located in the mounting seat 11. The socket 14 of the remote controller 10 protrudes outwardly from a back face of the mounting seat 11 and has an inside formed with a slot 15 facing downward. The slot 15 of the socket 14 has a flexible outer side 150.

The fixture 20 has a width smaller than that of the remote controller 10. The fixture 20 has a front face formed with a sliding space 22 slidably mounted on the mounting seat 11 of the remote controller 10 when the remote controller 10 is axially movable toward the fixture 20. The sliding space 22 of the fixture 20 has two sides respectively formed with two outwardly extending guide hooks 23 each slidably mounted on and guided by the respective guide rail 12 of the mounting seat 11 when the remote controller 10 is axially movable toward the fixture 20. The fixture 20 has a back face formed with a protruding bonding portion 21 that is attached to a wall or table by screwing or bonding. The fixture 20 has an upper end formed with an upward extending plug 24 detachably inserted into the slot 15 of the socket 14 of the remote controller 10 and rested on the outer side 150 of the slot 15 when the remote controller 10 is axially movable toward the fixture 20. The plug 24 of the fixture 20 has a back face provided with two opposite reinforcing ribs 25 each extending downward in an oblique way and each located between the plug 24 and the bonding portion 21. The reinforcing ribs 25 of the plug 24 are closely rested on the outer side 150 of the slot 15 when the plug 24 is inserted into the slot 15 of the socket 14 to prevent the remote controller 10 from being swayed or vibrated.

Accordingly, the fixture 20 is fully hidden in the back face of the remote controller 10, so that the fixture 20 is not exposed from the remote controller 10, thereby enhancing the aesthetic quality of the remote controller 10. In addition, the sliding space 22 of the fixture 20 is slidable on the mounting seat 11 of the remote controller 10, and the guide hooks 23 of the fixture 20 are guided by the guide rails 12 of the mounting seat 11 when the remote controller 10 is axially movable toward the fixture 20, so that the remote controller 10 is attached to the fixture 20 easily and rapidly, thereby facilitating a user attaching the remote controller 10 to the fixture 20. Further, the reinforcing ribs 25 of the plug 24 are closely rested on the outer side 150 of the slot 15 when the plug 24 is inserted into the slot 15 of the socket 14 to prevent the remote controller 10 from being swayed or vibrated.

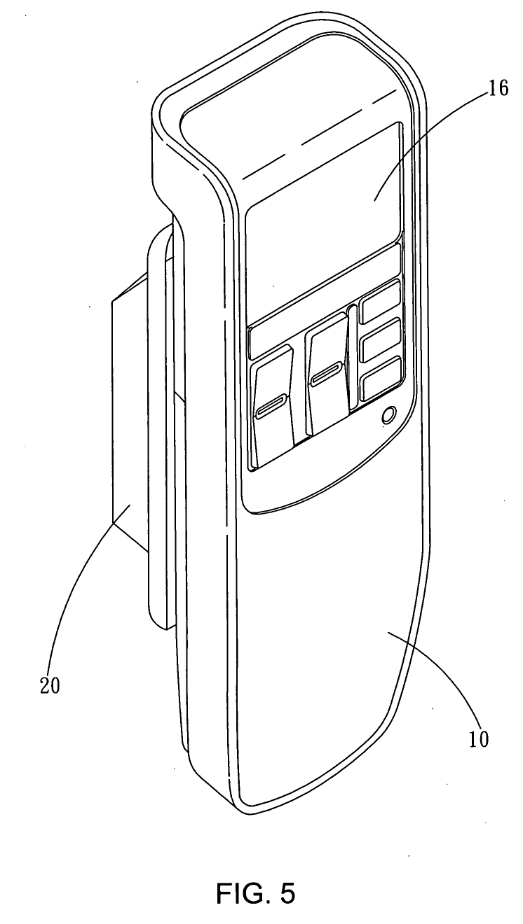

As shown in FIG. 5, the remote controller 10 is provided with a liquid crystal display 16 to indicate the related information of the remote controller 10, such as the picture, channel, volume and the like. Preferably, the liquid crystal display 16 is mounted on a front face of the remote controller 10.

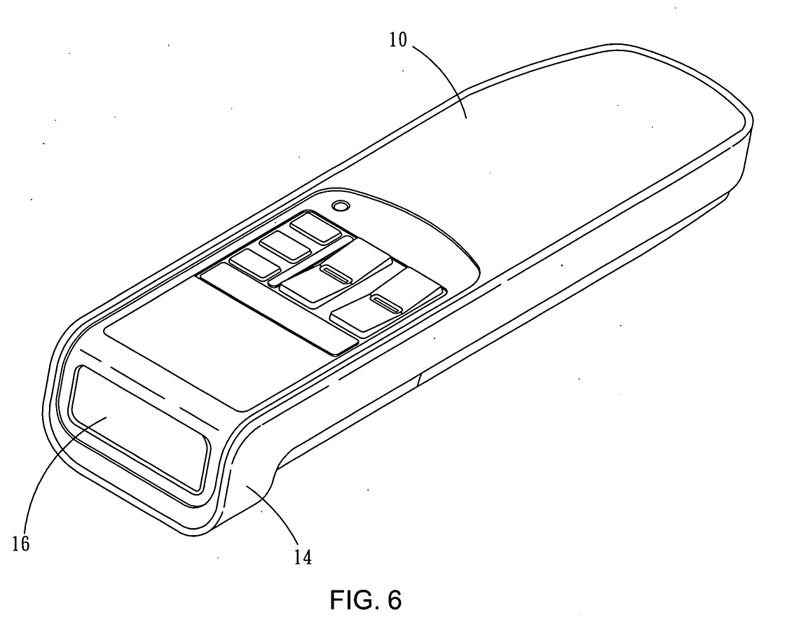

As shown in FIG. 6, the liquid crystal display 16 is mounted on a top face of the remote controller 10.

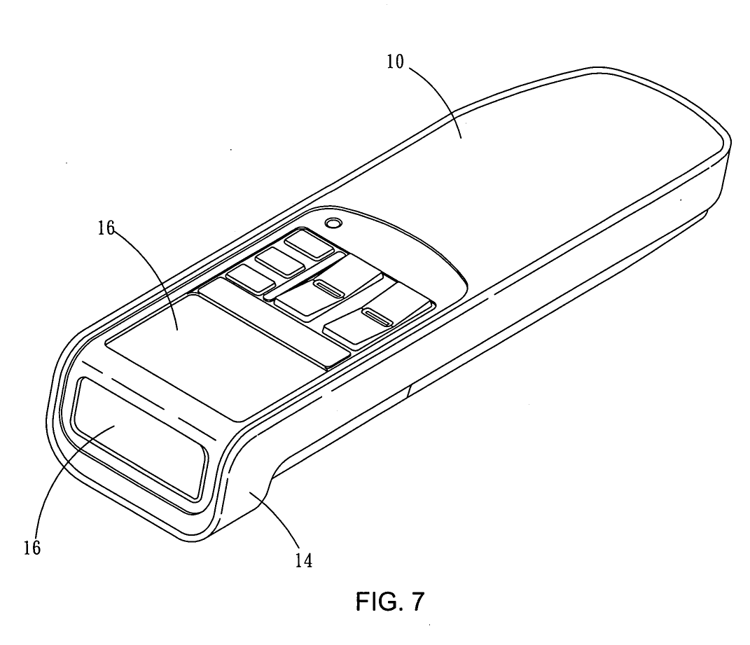

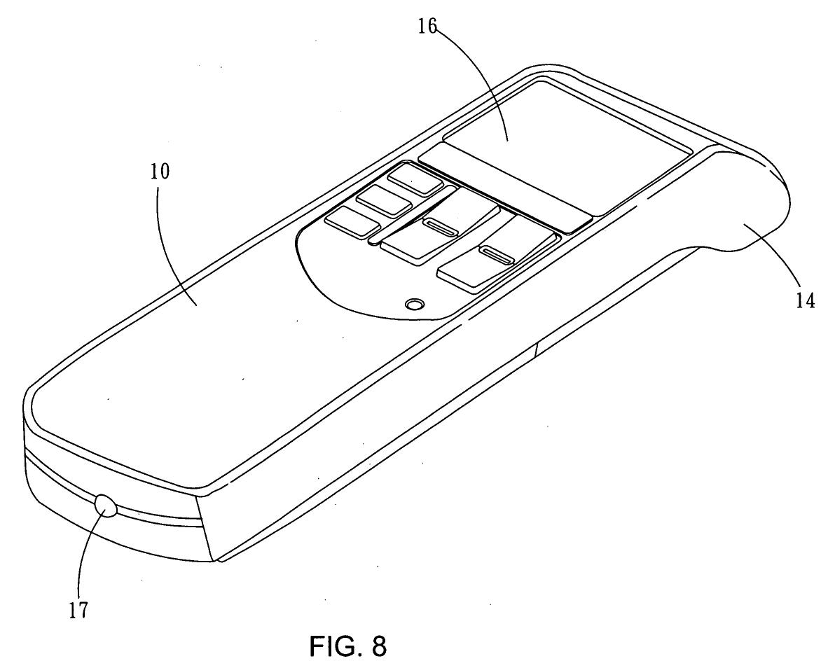

As shown in FIGS. 7 and 8, two liquid crystal displays 16 are mounted on a front face and a top face of the remote controller 10 respectively. Thus, the liquid crystal displays 16 display two different pictures to satisfy requirements of different users. In addition, the remote controller 10 is provided with an electric eye 17. Preferably, the electric eye 17 is mounted on a bottom face of the remote controller 10. Thus, the electric eye 17 functions as a signal emitter.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A remote controller assembly, comprising:
a remote controller;
a fixture detachably mounted on the remote controller and fully hidden in a back face of the remote controller.

2. The remote controller assembly in accordance with claim 1, wherein the back face of the remote controller is formed with a protruding mounting seat to support the fixture.

3. The remote controller assembly in accordance with claim 2, wherein the fixture has a front face formed with a sliding space slidably mounted on the mounting seat of the remote controller when the remote controller is axially movable toward the fixture.

4. The remote controller assembly in accordance with claim 3, wherein the mounting seat of the remote controller has two opposite sides formed with two parallel guide rails respectively, and the sliding space of the fixture has two sides respectively formed with two outwardly extending guide hooks each slidably mounted on and guided by the respective guide rail of the mounting seat when the remote controller is axially movable toward the fixture.

5. The remote controller assembly in accordance with claim 4, wherein the two guide rails of the mounting seat have a distance smaller than a width of the remote controller.

6. The remote controller assembly in accordance with claim 4, wherein each of the two guide rails of the mounting seat is gradually reduced toward a back face thereof.

7. The remote controller assembly in accordance with claim 4, wherein each of the two guide rails of the mounting seat has a lower portion gradually reduced downward.

8. The remote controller assembly in accordance with claim 2, wherein the remote controller has an upper end formed with an outwardly extending socket located above the mounting seat, the socket of the remote controller has an inside formed with a slot facing downward, and the fixture has an upper end formed with an upward extending plug detachably inserted into the slot of the socket of the remote controller when the remote controller is axially movable toward the fixture.

9. The remote controller assembly in accordance with claim 8, wherein the socket of the remote controller protrudes outwardly from a back face of the mounting seat.

10. The remote controller assembly in accordance with claim 8, wherein the slot of the socket has a flexible outer side.

11. The remote controller assembly in accordance with claim 10, wherein the plug of the fixture is rested on the outer side of the slot.

12. The remote controller assembly in accordance with claim 10, wherein the plug of the fixture has a back face provided with two opposite reinforcing ribs that are rested on the outer side of the slot when the plug is inserted into the slot of the socket.

13. The remote controller assembly in accordance with claim 12, wherein each of the reinforcing ribs of the plug extends downward in an oblique way.

14. The remote controller assembly in accordance with claim 12, wherein the fixture has a back face formed with a protruding bonding portion, and each of the reinforcing ribs of the plug is located between the plug and the bonding portion.

15. The remote controller assembly in accordance with claim 1, wherein the fixture has a back face formed with a protruding bonding portion.

16. The remote controller assembly in accordance with claim 1, wherein the fixture has a width smaller than that of the remote controller.

17. The remote controller assembly in accordance with claim 1, wherein the remote controller is provided with at least one liquid crystal display.

18. The remote controller assembly in accordance with claim 17, wherein the liquid crystal display is mounted on a front face or a top face of the remote controller.

19. The remote controller assembly in accordance with claim 1, wherein the remote controller is provided with two liquid crystal displays which are mounted on a front face and a top face of the remote controller respectively.

20. The remote controller assembly in accordance with claim 1, wherein the remote controller is provided with an electric eye which is mounted on a bottom face of the remote controller.
